(19) United States
(12) Patent Application Publication
(10) Pub. No.: US 2019/0393339 A1
(43) Pub. Date: Dec. 26, 2019

(54) HIGH-VOLTAGE SEMICONDUCTOR DEVICES AND METHODS FOR MANUFACTURING THE SAME

(71) Applicant: Vanguard International Semiconductor Corporation, Hsinchu (TW)

(72) Inventors: Chih-Hung LIN, Taichung City (TW); Chia-Hao LEE, New Taipei City (TW)

(73) Assignee: Vanguard International Semiconductor Corporation, Hsinchu (TW)

(21) Appl. No.: 16/018,515

(22) Filed: Jun. 26, 2018

(51) Int. Cl. H01L 29/78; H01L 29/10

(52) U.S. Cl. CPC H01L 29/7816; H01L 29/42368; H01L 29/1095; H01L 29/1083

(57) ABSTRACT

A method for manufacturing a high-voltage semiconductor device is provided. The method includes providing a substrate having a first conductive type. The method also includes performing a first ion implantation process so that a first doped region is formed in the substrate. The first doped region has a second conductive type that is different from the first conductive type. The method further includes forming a first epitaxial layer over the substrate. In addition, the method includes performing a second ion implantation process so that a second doped region is formed in the first epitaxial layer. The second doped region has the second conductive type, and the first doped region is in direct contact with the second doped region.

### BACKGROUND OF THE INVENTION

### Field of the Invention

The present invention relates to a semiconductor device, and in particular to a high-voltage semiconductor device with a buried layer and methods for manufacturing the same.

### Description of the Related Art

High-voltage semiconductor devices are applied to integrated circuits with high voltage and high power. Traditional high-voltage semiconductor devices, such as a vertically diffused metal oxide semiconductor (VDMOS) or a laterally diffused metal oxide semiconductor (LDMOS), are mainly used for devices operating on 18 volts or higher. The advantages of high-voltage device technology include cost effectiveness and process compatibility, and this is why high-voltage device technology has been widely used in display driver IC devices, power supply devices, and in such fields as power management, communications, automatics, and industrial control.

However, it is not satisfied in every respect as the density of ICs has improved. Therefore, it is necessary to develop a new high-voltage semiconductor device that can solve or improve upon the problems described above.

### BRIEF SUMMARY OF THE INVENTION

The disclosure provides a method for manufacturing a high-voltage semiconductor device. The method includes providing a substrate having a first conductive type. The method also includes performing a first ion implantation process so that a first doped region is formed in the substrate. The first doped region has a second conductive type that is different from the first conductive type. The method further includes forming a first epitaxial layer over the substrate. In addition, the method includes performing a second ion implantation process so that a second doped region is formed in the first epitaxial layer. The second doped region has the second conductive type, and the first doped region is in direct contact with the second doped region.

The disclosure provides a method for manufacturing a high-voltage semiconductor device. The method includes providing a substrate. The method also includes performing a first ion implantation process so that a first doped region is formed in the substrate. The method further includes forming a first epitaxial layer over the substrate. In addition, the method includes performing a second ion implantation process so that a second doped region is formed in the first epitaxial layer. The method also includes forming a second epitaxial layer over the first epitaxial layer. The first doped region and the second doped region form a buried layer which has a dopant concentration with a local minimum point along a direction from the first epitaxial layer towards the substrate.

The disclosure provides a method for manufacturing a high-voltage semiconductor device. The high-voltage semiconductor device includes a substrate having a first conductive type. The high-voltage semiconductor device also includes an epitaxial layer over the substrate. The high-voltage semiconductor device further includes a buried layer formed in the substrate and the epitaxial layer, wherein the buried layer has a second conductive type that is different from the first conductive type. In addition, the high-voltage semiconductor device includes a first high-voltage well region formed in the epitaxial layer, wherein the first high-voltage well region has the first conductive type. The high-voltage semiconductor device also includes a second high-voltage well region formed in the epitaxial layer and adjacent to the first high-voltage well region, wherein the second high-voltage well region has the second conductive type. The high-voltage semiconductor device further includes a gate structure disposed over the epitaxial layer, and includes a source region and a drain region disposed within the first high-voltage well region and the second high-voltage well region respectively, and on two opposite sides of the gate structure, wherein the dopant concentration of the buried layer has a local minimum point along a direction from the epitaxial layer towards the substrate.

### BRIEF DESCRIPTION OF THE DRAWINGS

The present invention can be more fully understood by reading the subsequent detailed description and examples with references made to the accompanying drawings, wherein:

FIGS. 1A-1H are cross-sectional representations of various stages of forming a high-voltage semiconductor device in accordance with some embodiments.

FIG. 2 is a cross-sectional representation of one stage of forming a high-voltage semiconductor device in accordance with some embodiments.

FIG. 3 is a distribution plot of the dopant concentration of a buried layer of a high-voltage semiconductor device, in accordance with some embodiments.

### DETAILED DESCRIPTION OF THE INVENTION

The high-voltage semiconductor device of the present disclosure is described in detail in the following description. In the following detailed description, for purposes of explanation, numerous specific details and embodiments are set forth in order to provide a thorough understanding of the present disclosure. The specific elements and configurations described in the following detailed description are set forth in order to clearly describe the present disclosure. It will be apparent, however, that the exemplary embodiments set forth herein are used merely for the purpose of illustration, and the inventive concept may be embodied in various forms without being limited to those exemplary embodiments. In addition, the drawings of different embodiments may use like and/or corresponding numerals to denote like and/or corresponding elements in order to clearly describe the present disclosure. However, the use of like and/or corresponding numerals in the drawings of different embodiments does not suggest any correlation between different embodiments. In addition, in this specification, expressions such as “first material layer disposed on/over a second material layer”, may indicate the direct contact of the first material layer and the second material layer, or it may indicate a non-contact state with one or more intermediate layers between the first material layer and the second material layer. In the above situation, the first material layer may not be in direct contact with the second material layer.

It should be noted that the elements or devices in the drawings of the present disclosure may be present in any form or configuration known to those skilled in the art. In addition, the expression “a layer overlying another layer”, “a layer is disposed above another layer”, “a layer is disposed on another layer” and “a layer is disposed over another layer” may indicate that the layer is in direct contact with the other layer, or that the layer is not in direct contact with the other layer, there being one or more intermediate layers disposed between the layer and the other layer.

In addition, in this specification, relative expressions are used. For example, “lower”, “bottom”, “higher” or “top” are used to describe the position of one element relative to another. It should be appreciated that if a device is flipped upside down, an element that is “lower” will become an element that is “higher”.

The terms “about” and “substantially” typically mean +/−20% of the stated value, more typically +/−10% of the stated value, more typically +/−5% of the stated value, more typically +/−3% of the stated value, more typically +/−2% of the stated value, more typically +/−1% of the stated value and even more typically +/−0.5% of the stated value. The stated value of the present disclosure is an approximate value. When there is no specific description, the stated value includes the meaning of “about” or “substantially”.

It should be understood that, although the terms first, second, third etc. may be used herein to describe various elements, components, regions, layers, portions and/or sections, these elements, components, regions, layers, portions and/or sections should not be limited by these terms. These terms are only used to distinguish one element, component, region, layer, portion or section from another region, layer or section. Thus, a first element, component, region, layer, portion or section discussed below could be termed a second element, component, region, layer, portion or section without departing from the teachings of the present disclosure.

Unless defined otherwise, all technical and scientific terms used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined.

This description of the exemplary embodiments is intended to be read in connection with the accompanying drawings, which are to be considered part of the entire written description. The drawings are not drawn to scale. In addition, structures and devices are shown schematically in order to simplify the drawing.

In the description, relative terms such as “lower,” “upper,” “horizontal,” “vertical,”, “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

The term “substrate” is meant to include devices formed within a transparent substrate and the layers overlying the transparent substrate. All transistor element needed may be already formed over the substrate. However, the substrate is represented with a flat surface in order to simplify the drawing. The term “substrate surface” is meant to include the uppermost exposed layers on a transparent substrate, such as an insulating layer and/or metallurgy lines.

The thickness of a structure described in the embodiments of the disclosure indicates a value for the average thickness of the structure after deleting outliers. The outliers can be the thickness of an edge, an obvious micro-trench, or an obvious micro-raised area. After deleting the outliers, most values for thickness are within three standard deviations.

It should also be noted that the present disclosure presents embodiments of a high-voltage semiconductor device, and may be included in an integrated circuit (IC) such as a microprocessor, memory device, and/or another IC. The IC may also include various passive and active microelectronic devices, such as thin film resistors, other capacitors (e.g. metal-insulator-metal capacitor, MIMCAP), inductors, diodes, metal-oxide-semiconductor field effect transistors (MOSFETs), complementary MOS (CMOS) transistors, bipolar junction transistors (BJTs), laterally diffused MOS (LDMOS) transistors, high power MOS transistors, or other types of transistors. One of ordinary skill may recognize other embodiments of semiconductor devices that may benefit from aspects of the present disclosure.

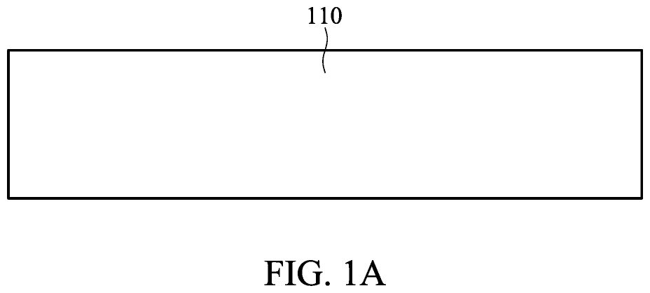

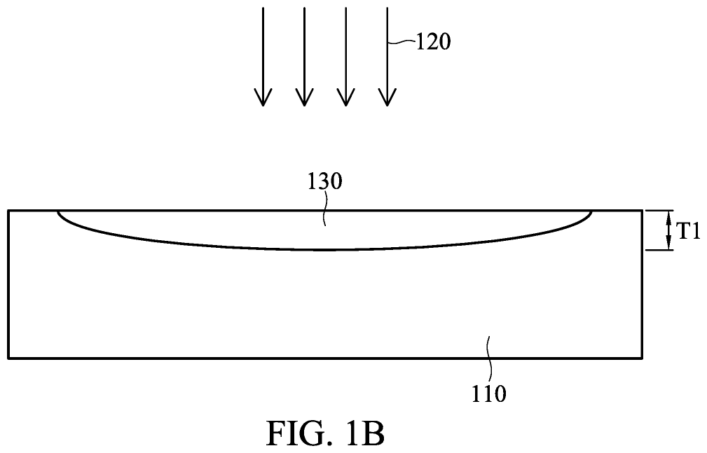

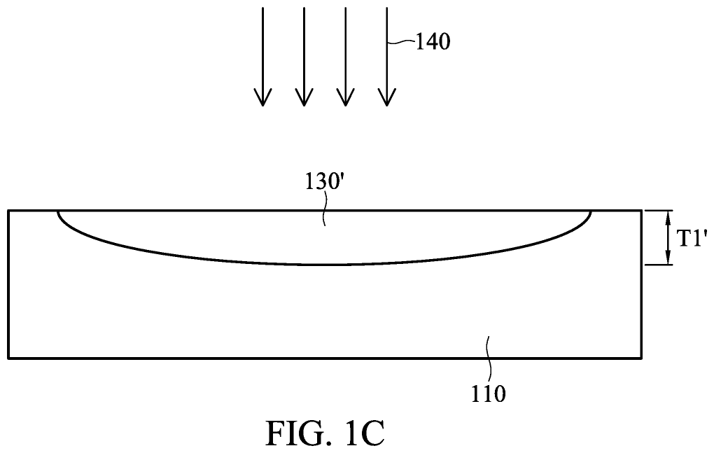

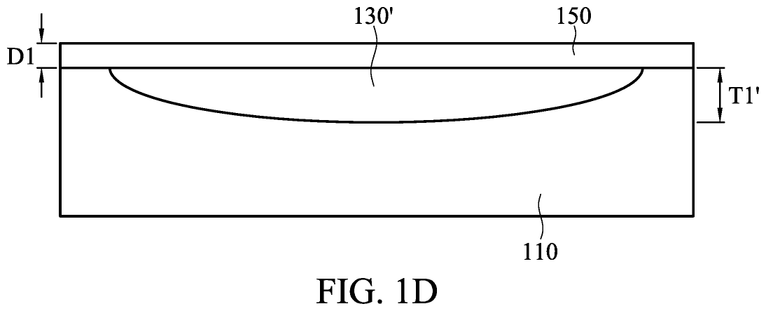

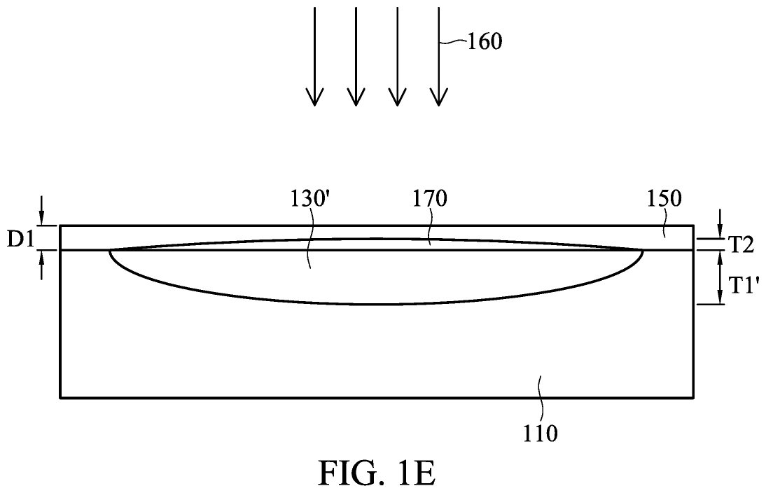

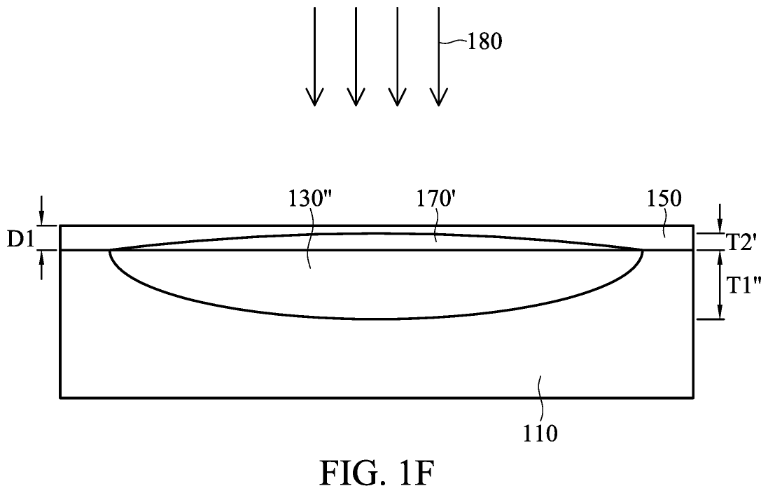

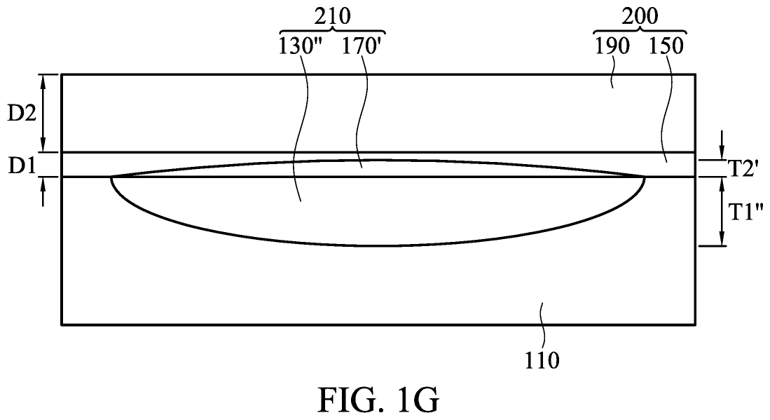

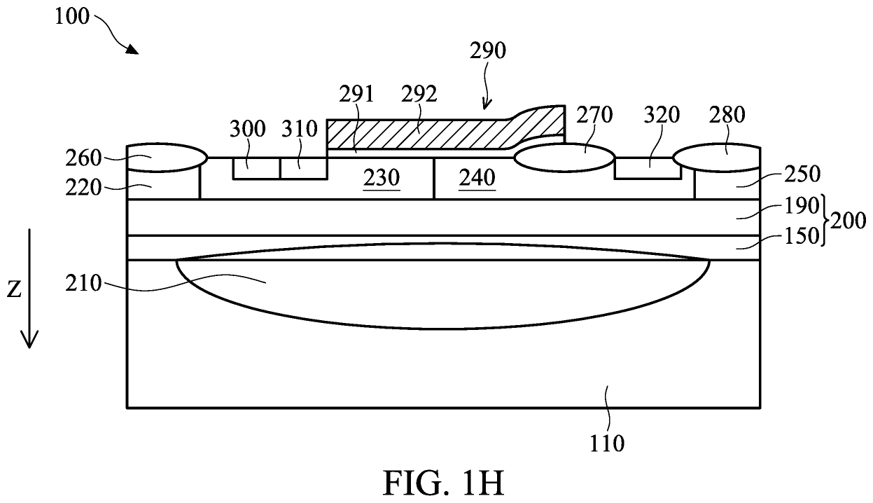

As shown in FIG. 1A, a substrate 110 is provided. The substrate 110 may be a semiconductor substrate, such as a bulk semiconductor, a semiconductor-on-insulator (SOI) substrate, or the like, which may be doped (e.g., with a p-type or an n-type dopant) or undoped. The substrate 110 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 110 may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. In some embodiments, the substrate 110 has a first conductive type, such as P type.

In some embodiments, as shown in FIG. 1B, a first implantation process 120 is performed to form a first doped region 130 in the substrate 110. In some embodiments, the first doped region 130 has a second conductive type that is different from the first conductive type, such as N type. The dopant of the first doped region 130 includes group 15 (group VA) elements, such as nitrogen (N), phosphor (P), arsenic (As), antimony (Sb) or a combination thereof. As shown in FIG. 1B, the first doped region 130 has a thickness T1. In some embodiments, the thickness T1 is in a range of about 0.1 μm to about 1 μm.

In some embodiments, the dopant of the first doped region 130 is Sb. In some embodiments, the implantation energy of the first implantation process 120 is in a range of about 3 keV to about 140 keV. In some embodiments, the dosage of the dopant during the first implantation process 120 is in a range of about 10¹³ atoms/cm² to about 10¹⁵ atoms/cm².

In some embodiments, as shown in FIG. 1C, a thermal process 140 is performed to diffuse the dopant of the first doped region 130. As a result, a first doped region 130′ is performed. In some embodiments, the temperature of the thermal process 140 is in a range of about 900° C. to about 1100° C. . In some embodiments, the first doped region 130′ has a thickness T1′. In some embodiments, the thickness T1′ is in a range of about 1 μm to about 3 μm. In some embodiments, the thermal process 140 is not performed.

In some embodiments, as shown in FIG. 1D, a first epitaxial layer 150 is formed on the substrate 110. The first epitaxial layer 150 may include, but is not limited to, Si, Ge, SiGe, III-V compound, or a combination thereof. The first epitaxial layer 150 may be formed by an epitaxial growth step, such as metal-organic chemical vapor deposition (MOCVD), metal-organic vapor phase epitaxy (MOVPE), plasma-enhanced chemical vapor deposition (PECVD), remote plasma-enhanced chemical vapor deposition (RP-CVD), molecular beam epitaxy (MBE), hydride vapor phase epitaxy (HVPE), liquid phase epitaxy (LPE), chloride vapor phase epitaxy (Cl-VPE), or any other suitable method. In some embodiments, the first epitaxial layer 150 has the first conductive type such as P type.

In some embodiments, the first epitaxial layer 150 has a thickness D1 which is in a range of about 0.5 μm to about 1.5 μm. In the embodiments where the thermal process 140 is not performed, the dopants of the first doped region 130 are diffused due to the high temperature of the formation of the first epitaxial layer 150.

In some embodiments, as shown in FIG. 1E, a second implantation process 160 is performed so that a second doped region 170 is formed in the first epitaxial layer 150. In some embodiments, the second doped region 170 has the second conductive type such as N type. The dopant of the second doped region 170 includes group 15 (or group VA) elements, such as N, P, As, Sb or a combination thereof. As shown in FIG. 1E, the second doped region 170 has a thickness T2. In some embodiments, the thickness T2 is in a range of about 0.1 μm to about 1 μm.

In some embodiments, the dopant of the second doped region 170 is Sb. In some embodiments, the implantation energy of the second implantation process 160 is in a range of about 3 keV to about 140 keV. In some embodiments, the dosage of the dopant during the second implantation process 160 is in a range of about 10¹³ atoms/cm² to about 10¹⁵ atoms/cm². In some embodiments, the second implantation process 160 is in situ implantation where the first epitaxial layer 150 and the second implantation process 160 are performed in the same chamber.

In some embodiments, as shown in FIG. 1E, the second doped region 170 is in direct contact with the first doped region 130′ after the second implantation process 160 is performed.

Many variations and/or modifications can be made to embodiments of the disclosure. In some embodiments, the second doped region 170 is not in direct contact with the first doped region 130′ after the second implantation process 160 is performed and before a subsequent annealing process.

In some embodiments, as shown in FIG. 1F, an annealing process 180 is performed to diffuse the dopant of the first doped region 130′ and the second doped region 170. As a result, a first doped region 130″ and a second doped region 170′ are formed. After the second implantation process 160 is performed, the first epitaxial layer 150 is amorphous. In order to form a second epitaxial layer subsequently on the first epitaxial layer 150, the annealing process 180 is performed so that the first epitaxial layer 150 becomes single crystal.

In some embodiments, as shown in FIG. 1F, the first doped region 130″ has a thickness T1″ and a second doped region 170′ has a thickness T2′ after the annealing process 180 is performed. In some embodiments, the thickness T1″ is in a range of about 2.5 μm to about 5 μm. In some embodiments, the thickness T2′ is in a range of about 0.5 μm to about 1.5 μm. In some embodiments, the first doped region 130″ is in direct contact with the second doped region 170′ after the annealing process 180 is performed.

The annealing process 180 may be a rapid thermal anneal (RTA) where the temperature is in a range of about 900° C. to about 1100° C. . The annealing process 180 may also be a spike annealing where the temperature is in a range of about 950° C. to about 1050° C. and the time period is in a range between about 1 second and 2 seconds.

In some embodiments, as shown in FIG. 1G, a second epitaxial layer 190 is formed over the first epitaxial layer 150. In some embodiments, the material and the formation method of the second epitaxial layer 190 are the same as or similar to those of the first epitaxial layer 150, and are not repeated herein. In some embodiments, the second epitaxial layer 190 has a thickness D2 greater than the thickness D1. In some embodiments, the thickness D2 is in a range of about 4 μm to about 20 μm.

As shown in FIG. 1G, the first epitaxial layer 150 and the second epitaxial layer 190 may be regarded as an epitaxial layer 200 of the high-voltage semiconductor device, and the first doped region 130″ and the second doped region 170′ form a buried layer 210 of the high-voltage semiconductor device, such as a N type buried layer or a P type buried layer. The formation of the buried layer 210 assists in reduction of the leakage of the high-voltage semiconductor device. In some embodiments, the thickness of the buried layer 210 is in a range of about 3 μm to about 6.5 μm.

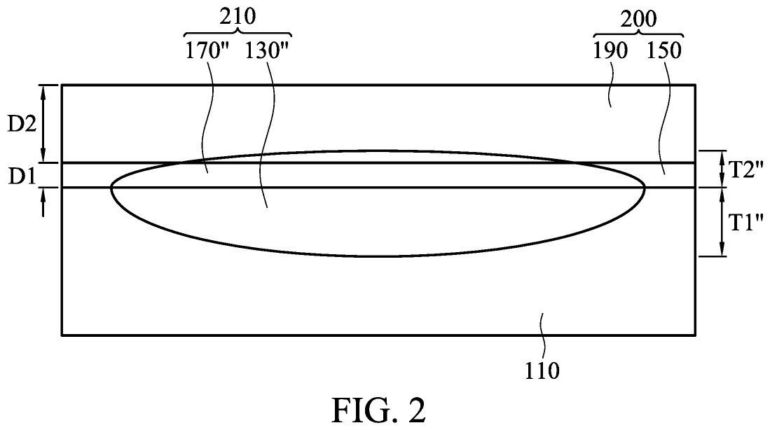

Many variations and/or modifications can be made to embodiments of the disclosure. In some embodiments, as shown in FIG. 2, the dopant of the second doped region 170′ could further diffuse to the second epitaxial layer 190 after the formation of the second epitaxial layer 190. As a result, a second doped region 170″ is formed. In this embodiment, the second doped region 170″ has a thickness T2″ in a range of about 1 μm to about 5 μm, and the thickness of the buried layer 210 is in a range of about 3.5 μm to about 10 μm.

Since the second implantation process 160 and the annealing process 180 are performed between the formation of the first epitaxial layer 150 and that of the second epitaxial layer 190, there is a boundary at an interface between the first epitaxial layer 150 and the second epitaxial layer 190.

In some embodiments, as shown in FIG. 1H, a high-voltage well region 220, a high-voltage well region 230, a high-voltage well region 240 and a high-voltage well region 250 are formed in the second epitaxial layer 190 and over the buried layer 210. The high-voltage well region 220 and the high-voltage well region 240 have the second conductive type such as N type. The high-voltage well region 230 and the high-voltage well region 250 have the first conductive type such as P type. The dopant concentration of the high-voltage well regions 220, 230, 240 and 250 is in a range of about 10¹⁴ atoms/cm³ to about 10¹⁷ atoms/cm³.

Next, as shown in FIG. 1H, an isolation region 260, an isolation region 270 and an isolation region 280 are formed. In some embodiments, the isolation region 260, the isolation region 270 and the isolation region 280 are field oxide regions formed by oxidation of silicon. As shown in FIG. 1H, the isolation region 260 covers a portion of the high-voltage well region 220 and the high-voltage well region 230. The isolation region 270 covers a portion of the high-voltage well region 240. The isolation region 280 covers a portion of the high-voltage well region 240 and the high-voltage well region 250.

Next, as shown in FIG. 1H, a gate structure 290 is formed over the epitaxial layer 200. A gate structure 290 is formed over the second epitaxial layer 190. As shown in FIG. 1H, the gate structure 290 includes a gate dielectric layer 291 and a gate electrode 292. The material of the gate dielectric layer 291 may include, but is not limited to, silicon oxide, silicon nitride, silicon oxynitride, high-k material, any other suitable dielectric material, or a combination thereof. The high-k material may include, but is not limited to, metal oxide, metal nitride, metal silicide, transition metal oxide, transition metal nitride, transition metal silicide, transition metal oxynitride, metal aluminate, zirconium silicate, zirconium aluminate. For example, the material of the high-k material may include, but is not limited to, LaO, AlO, ZrO, TiO, Ta₂O₅, Y₂O₃, SrTiO₃(STO), BaTiO₃(BTO), BaZrO, HfO₂, HfO₃, HfZrO, HfLaO, HfSiO, HfSiON, LaSiO, AlSiO, HfTaO, HfSiO, HfTaTiO, HfAlON, (Ba,Sr)TiO₃(BST), Al₂O₃, any other suitable high-k dielectric material, or a combination thereof. The gate dielectric layer 291 may be formed by chemical vapor deposition or spin-on coating. The chemical vapor deposition may include, but is not limited to, low pressure chemical vapor deposition (LPCVD), low temperature chemical vapor deposition (LTCVD), rapid thermal chemical vapor deposition (RTCVD), plasma enhanced chemical vapor deposition (PECVD), atomic layer deposition (ALD), or any other suitable method.

The material of the gate electrode 292 may include, but is not limited to, amorphous silicon, poly-silicon, one or more metal, metal nitride, conductive metal oxide, or a combination thereof. The metal may include, but is not limited to, molybdenum, tungsten, titanium, tantalum, platinum, or hafnium. The metal nitride may include, but is not limited to, molybdenum nitride, tungsten nitride, titanium nitride or tantalum nitride. The conductive metal oxide may include, but is not limited to, ruthenium oxide or indium tin oxide. The conductive material layer may be formed by the previous described chemical vapor deposition (CVD), sputtering, resistive thermal evaporation, electron beam evaporation, or any other suitable methods.

In addition, the gate dielectric layer 291 and the gate electrode 292 may be formed by suitable lithography and etching processes. The photolithography process includes photoresist coating (e.g., spin-on coating), soft baking, mask alignment, exposure, post-exposure baking, developing the photoresist, rinsing and drying (e.g., hard baking). The photolithography process may also be implemented or replaced by another proper method such as maskless photolithography, electron-beam writing or ion-beam writing. The etching process may include dry etching, wet etching, and other etching methods such as reactive ion etching (RIE). Furthermore, the etching process may also include purely chemical etching (plasma etching), purely physical etching (ion milling), or a combination thereof.

Moreover, as shown in FIG. 1H, the gate structure 290 is disposed over a portion of the high-voltage well region 230 and the high-voltage well region 240. In addition, a portion of the gate structure 290 is formed conformally over the isolation region 270.

In some embodiments, as shown in FIG. 1H, a body region 300, a source region 310 and a drain region 320 are formed in the second epitaxial layer 190. The body region 300 and the source region 310 are formed in the high-voltage well region 230, and the drain region 320 is formed in the high-voltage well region 240. In some embodiments, the source region 310 and the drain region 320 have the second conductive type such as N type, and have dopant concentration in a range of about 10¹⁸ atoms/cm³ to about 10²¹ atoms/cm³. The body region 300 has the first conductive type such as P type, and has dopant concentration in a range of about 10¹⁸ atoms/cm³ to about 10²¹ atoms/cm³. The body region 300, the source region 310 and the drain region 320 may be formed by ion an implantation or a diffusion process, and implanted dopants are activated by RTA process.

As shown in FIG. 1H, the source region 310 and the drain region 320 are formed on two opposite sides of the gate structure 290, and the body region 300 is formed adjacent to the source region 310. As a result, a high-voltage semiconductor device 100 is created.

In some embodiments, Sb is selected to be used as the dopant of the buried layer. Sb is heavier element. Therefore, after Sb atoms are implanted into the substrate and/or the epitaxial layer, it is not effective to diffuse Sb atoms by a thermal process. If only one ion implantation process and one thermal process are performed, the thickness of the buried layer is smaller than 3 μm. If the buried layer is too thinner, it may not be easy to refrain from leakage.

In addition, since Sb is heavier element, it needs more implantation energy to perform the ion implantation process. Accordingly, it has difficulty on formation of a buried layer with thicker thickness and high dopant concentration greater than 10¹⁷ atoms/cm³. According to the embodiments of the present disclosure, a first portion of the dopant is implanted to the substrate to form a first doped region before the formation of the first epitaxial layer. Next, a thinner first epitaxial layer is formed, and then a second portion of the dopant is implanted to the first epitaxial layer to form a second doped region. Next, a second epitaxial layer that is thicker than the first epitaxial layer is formed. Finally, the first doped region and the second doped region form a buried layer. The buried layer with greater thickness and dopant concentration is formed using methods which use at least two separate ion implantation processes. In addition, forming the buried layer using two separate ion implantation processes is less expensive than using a spin-on-glass (SOG) process. Moreover, unlike the use of a spin-on-glass process, additional tools and/or equipment are not necessary.

In addition, in some embodiments, the formation of a thinner first epitaxial layer enables the first doped region to be in direct contact with the second doped region after the formation of the second doped region. Therefore, the first doped region and the second doped region form the buried layer. Furthermore, the second epitaxial layer may be formed with the desired thickness after the first epitaxial layer is formed and the annealing process is performed. In some embodiments, a buried layer that is thicker than 5 μm and has a concentration that is higher than 10¹⁷ atoms/cm³ is formed in a SOG process.

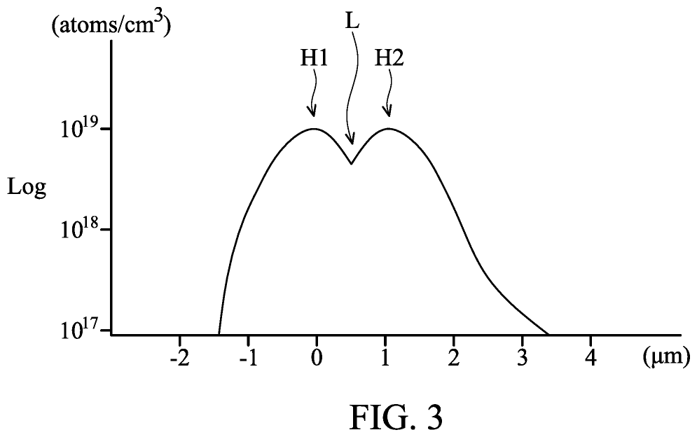

FIG. 3 illustrates a distribution plot of the dopant concentration of the buried layer 210 of the high-voltage semiconductor device 100. The X-axis represents the depth of the dopant, and the Y-axis represents the concentration of the dopant. Regarding the X-axis, an interface between the substrate 110 and the epitaxial layer 200 is defined as zero, and the more positive the X-axis is, the farther from the epitaxial layer 200 the position within the substrate 110 is. Similarly, the more negative the X-axis is, the farther from the substrate 110 the position within the epitaxial layer 200 is. As shown in FIG. 3, the concentration of the dopant has a local minimum point L along a direction (such as Z direction) from the epitaxial layer 200 towards the substrate 110 shown in FIG. 1H due to two separate ion implantation processes. In some embodiments, the local minimum point L is located in the substrate 110.

In addition, as shown in FIG. 3, the thickness of the portion with concentration greater than 10¹⁷ atoms/cm³ is equivalent to or greater than 5 μm. In some embodiments, the concentration of the dopant has a local maximum point H1 and a local maximum point H2. The local maximum point H1 is located in the epitaxial layer 200, and adjacent to the interface between the epitaxial layer 200 and the substrate 110. The local maximum point H2 is located in the substrate 110. In some embodiments, as shown in FIG. 3, at least a portion of the dopant concentration of the buried layer 210 is in a range of about 10¹⁷ atoms/cm³ to about 10¹⁹ atoms/cm³. In some embodiments, the thickness of the portion of the buried layer 210 with concentration greater than 10¹⁷atoms/cm³ is in a range of 3 μm to about 6.5 μm. In some embodiments, the thickness of the portion of the buried layer 210 with concentration greater than 10¹⁷ atoms/cm³ is in a range of 3.5 μm to about 10 μm.

Although some embodiments of the present disclosure and their advantages have been described in detail, it should be understood that various changes, substitutions and alterations can be made herein without departing from the spirit and scope of the disclosure as defined by the appended claims. For example, it will be readily understood by those skilled in the art that many of the features, functions, processes, and materials described herein may be varied while remaining within the scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A method for manufacturing a high-voltage semiconductor device, comprising:
providing a substrate having a first conductive type;
performing a first ion implantation process so that a first doped region is formed in the substrate, wherein the first doped region has a second conductive type that is different from the first conductive type;
forming a first epitaxial layer over the substrate; and
performing a second ion implantation process so that a second doped region is formed in the first epitaxial layer, wherein the second doped region has the second conductive type, and the first doped region is in direct contact with the second doped region.

2. The method as claimed in claim 1, further comprising:
forming a second epitaxial layer over the first epitaxial layer.

3. The method as claimed in claim 2, wherein the first epitaxial layer has a first thickness and the second epitaxial layer has a second thickness that is greater than the first thickness.

4. The method as claimed in claim 1, further comprising:
performing a first thermal process to diffuse the first doped region before the first epitaxial layer is formed.

5. The method as claimed in claim 1, further comprising:
Performing an annealing process to diffuse the first doped region and the second doped region after the second ion implantation process is performed.

6. The method as claimed in claim 1, wherein the first doped region and the second doped region form a buried layer which has a dopant concentration in a range of about 10¹⁷ atoms/cm³ to about 10¹⁹ atoms/cm³.

7. The method as claimed in claim 6, wherein the dopant of the buried layer comprises antimony (Sb).

8. The method as claimed in claim 6, wherein the dopant concentration of the buried layer has a local minimum point along a direction from the first epitaxial layer towards the substrate.

9. A method for manufacturing a high-voltage semiconductor device, comprising:
providing a substrate;
performing a first ion implantation process so that a first doped region is formed in the substrate;
forming a first epitaxial layer over the substrate;
performing a second ion implantation process so that a second doped region is formed in the first epitaxial layer;
forming a second epitaxial layer over the first epitaxial layer;
wherein the first doped region and the second doped region form a buried layer which has a dopant concentration with a local minimum point along a direction from the first epitaxial layer towards the substrate.

10. The method as claimed in claim 9, wherein the local minimum point of the dopant concentration of the buried layer is within the substrate.

11. A high-voltage semiconductor device, comprising:
a substrate having a first conductive type;
an epitaxial layer disposed over the substrate;
a buried layer formed in the substrate and the epitaxial layer, wherein the buried layer has a second conductive type that is different from the first conductive type;
a first high-voltage well region formed in the epitaxial layer, wherein the first high-voltage well region has the first conductive type;
a second high-voltage well region formed in the epitaxial layer and adjacent to the first high-voltage well region, wherein the second high-voltage well region has the second conductive type;
a gate structure disposed over the epitaxial layer; and
a source region and a drain region disposed within the first high-voltage well region and the second high-voltage well region respectively, and on two opposite sides of the gate structure,
wherein the dopant concentration of the buried layer has a local minimum point along a direction from the epitaxial layer towards the substrate.

12. The high-voltage semiconductor device as claimed in claim 11, wherein the epitaxial layer comprises:
a first epitaxial layer; and
a second epitaxial layer disposed over the first epitaxial layer,
wherein the buried layer is formed in the first epitaxial layer and the substrate.

13. The high-voltage semiconductor device as claimed in claim 12, wherein there is a boundary at an interface between the first epitaxial layer and the second epitaxial layer.

14. The high-voltage semiconductor device as claimed in claim 12, wherein the buried layer is further formed in the second epitaxial layer.

15. The high-voltage semiconductor device as claimed in claim 12, wherein the first epitaxial layer has a first thickness and the second epitaxial layer has a second thickness that is greater than the first thickness.

16. The high-voltage semiconductor device as claimed in claim 11, wherein the buried layer has a thickness in a range of about 3 μm to about 6.5 μm.

17. The high-voltage semiconductor device as claimed in claim 11, wherein the buried layer has a dopant concentration in a range of about 10¹⁷ atoms/cm³ to about 10¹⁹ atoms/cm³.

18. The high-voltage semiconductor device as claimed in claim 11, wherein the dopant of the buried layer comprises antimony (Sb).

19. The high-voltage semiconductor device as claimed in claim 11, wherein the local minimum point of the dopant concentration of the buried layer is within the substrate.

20. The high-voltage semiconductor device as claimed in claim 19, wherein the dopant concentration of the buried layer further comprises:
a first local maximum point within the epitaxial layer; and
a second local maximum point within the substrate.
